(19) United States
(12) Patent Application Publication
(10) Pub. No.: US 2013/0026329 A1
(43) Pub. Date: Jan. 31, 2013

(54) COLLAPSIBLE STAND FOR SUPPORTING A PORTABLE ELECTRONIC DEVICE

(71) Applicants: Ron Lane, Spring Valley, NY (US); Richard Kligman, Ramat Bet Shemesh (IL); Robert Pettiford, Leesburg, VA (US)

(72) Inventors: Ron Lane, Spring Valley, NY (US); Richard Kligman, Ramat Bet Shemesh (IL); Robert Pettiford, Leesburg, VA (US)

(21) Appl. No.: 13/576,744

(22) PCT Filed: Feb. 17, 2011
(86) PCT No.: PCT/US11/25143

§ 371 Date: Aug. 2, 2012

Related U.S. Application Data
(60) Provisional application No. 61/306,958, filed on Feb. 23, 2010.

(51) Int. Cl. H05K 7/18

(52) U.S. Cl. 248/459; 248/174

(57) ABSTRACT

A collapsible, lightweight, easily portable stand for supporting a portable electronic device such as an iPhone, iPad, cell phone, or ebook reader, that allows the user to view what is displayed on the device without supporting it with his hand. The stand alternates easily between a collapsed state which is compact and easy to transport, and an open position that permits convenient viewing. The stand comprises a front panel, two side panels, a back panel, and a bottom panel. The back and front panel can selectively attach and unattach. The bottom panel can selectively mate with the front panel for smaller devices, or the back panel for larger devices.

### FIELD OF THE INVENTION

The present invention relates to the field of supporting stands. In particular, the present invention relates to the field of collapsible supporting stands. More particularly, the present invention relates to the field of supporting stands for electronic devices.

### BACKGROUND OF THE INVENTION

A user of a portable electronic device, such as an iPhone, iTouch, iPad, cell phone, e-book reader, Playstation Portable, etc. typically views the screen of the device numerous times throughout the day, often for extended periods of time. When viewing the screen, the device is generally held in the user's hand, which may result in fatigue of the hand.

If available, a user may utilize a makeshift stand such as an object on a desk, for example, a computer screen, telephone, etc. for propping up the device in order to free up his hands to either rest or perform other activities. However, it is not practical to transport such a stand along with the portable electronic device. The user must therefore find a creative solution for propping up the device at each location he stops at. There exist prior art stands that are designed for supporting an electronic device, however, they are bulky and cannot be conveniently transported, for instance, in one's pocket, along with the portable electronic device.

It would be beneficial for the user to have a supporting stand that is lightweight and capable of collapsing such that the user may conveniently transport and easily open the stand to rest the device thereon. Such a stand should allow the user to view the screen and generally operate the device while the device rests thereon.

### SUMMARY OF THE INVENTION

Accordingly, it is a principal object of the present invention to provide a collapsible stand for supporting a portable electronic device, which overcomes the difficulties and drawbacks associated with the prior art as described in part, herein above.

Another object of the present invention is to provide a stand capable of supporting and propping up a portable electronic device such as an iPhone, iTouch, iPad, cell phone, e-book reader, Playstation Portable, etc. in its vertical or horizontal viewing positions.

Another object of the present invention is to provide a collapsible stand that may be maintained in its closed position without unintentionally opening.

Another object of the present invention is to provide a durable collapsible stand that may be maintained in its open position without unintentionally collapsing.

Another object of the present invention is to provide a stable collapsible stand that may be maintained upright in its open position without falling over due to the weight or design of a portable electronic device, such as an e-book reader.

Another object of the present invention is to provide a collapsible stand that is manufactured from inexpensive materials, via a manufacturing process that is inexpensive.

Another object of the present invention is to provide a collapsible stand that requires little or no skill to operate.

In accordance with a preferred embodiment of the present invention, there is provided a stand for supporting a portable electronic device. The stand comprises a front panel, two side panels, a back panel and a bottom panel. The stand comprises an open position and a closed position, wherein the stand is selectively shiftable between the open position and the closed position, and wherein when the stand is in the open position the bottom panel is selectively coupled with at least one of the front panel and the back panel.

Each side panel is foldable and unfoldable for selectively shifting the stand between the closed position and the open position. Moreover, each side panel comprises an upper vertical edge, wherein the edge extends from the back panel to the front panel, and wherein the back panel is vertically higher than the front panel such that the edge extends descendingly from the back panel to the front panel.

A portion of each vertical edge near the front panel extends vertically lower than the height of the front panel thereby creating a seat for allowing an electronic device to rest in the vertically lower portion when the stand is in the open position.

When the stand is in the closed position, the folded side panels cover at least a portion of the back panel.

Each side panel comprises a lower vertical edge, wherein the edge extends from the back panel to the front panel, and wherein the edge comprises a cutout portion cut into the side panel, wherein when the stand is in the closed position a portion of the back panel is exposed by the cutout portions of the side panels.

When the stand is in the closed position the front panel is releasably securable to the back panel by a coupling mechanism. The coupling mechanism comprises a first component located on the exposed portion of the back panel and a second component located on the opposing face of the front panel. In one aspect, the coupling mechanism comprises a snap mechanism, wherein one of the front panel and the back panel comprises a snap stud and the other of the front panel and the back panel comprises a snap socket. In an alternative aspect, the coupling mechanism comprises hook and loop fasteners such as Velcro™, wherein one of the front panel and the back panel comprises hook fasteners and the other of the front panel and the back panel comprises loop fasteners. In yet an alternative aspect, the coupling mechanism comprises an adhesive material on at least one of the front panel and back panel for selectively securing and releasing one of the front panel and back panel to the other of the front panel and back panel.

The bottom panel preferably extends from the back panel and comprises a free end having a coupling member, and wherein the front panel comprises a receiving portion for joining the coupling member to the front panel. The receiving portion is preferably an opening in the front panel for inserting the coupling member therein. The opening preferably comprises a slit for allowing the coupling member to be inserted through the opening, while preventing the coupling member from being released unintentionally from the opening.

Alternatively, the front panel comprises an extension element having a receiving portion for joining the coupling member thereto. The receiving portion is an opening in the extension element for inserting the coupling member therein. The receiving portion is an opening created at the juncture between the extension element and the front panel. The opening preferably comprises a slit for allowing the coupling member to be inserted through the opening, while preventing the coupling member from being released unintentionally from the opening.

Preferably, the back panel comprises a receiving portion for joining the coupling member to the back panel. The receiving portion is preferably an opening in the back panel for inserting the coupling member therein. The opening preferably comprises at least one slit for allowing the coupling member to be inserted through the opening, while preventing the coupling member from being released unintentionally from the opening.

The bottom panel is extendable behind the back panel, wherein back panel comprises a first surface facing the front panel and a second surface facing away from the front panel, wherein the coupling member is inserted through the opening at the second surface of the back panel.

The portable electronic device may be chosen from the list consisting of a cellular phone, iPhone, iTouch, iPad, ebook reader, and Playstation portable, or similar electronic devices.

In accordance with an alternative embodiment of the present invention, there is provided a stand for supporting a portable electronic device, the stand comprising a front panel, two side panels and a back panel, wherein the stand comprises an open position and a closed position, and wherein the stand is selectively shiftable between the open position and the closed position, and wherein when the stand is in the closed position the front panel is releasably securable to the back panel by a coupling mechanism.

Additional objects and advantages of the invention will become apparent as the description proceeds.

### BRIEF DESCRIPTION OF THE FIGURES

To accomplish the above and related objects, the invention may be embodied in the form illustrated in the accompanying drawings, attention being called to the fact, however, that the drawings are illustrative only, and that changes may be made in the specific construction illustrated and described.

FIG. 1 shows an unfolded view of the stand of the present invention;

FIG. 2 shows an assembled front isometric view of the stand of the present invention;

FIGS. 3a and 3b show a bottom isometric view of the stand of the present invention with the bottom panel in a preparatory position for coupling with the front panel (FIG. 3a), and coupled with the front panel (FIG. 3b);

FIG. 4 shows a small electronic device leaning on the upper edges of the side panels in a longitudinally oriented manner;

FIG. 5 shows a small electronic device leaning on the upper edges of the side panels in a transversally oriented manner;

FIGS. 6a and 6b show a back isometric view of the stand of the present invention with the bottom panel in a preparatory position for coupling with the back panel (FIG. 6a), and coupled with the back panel (FIG. 6b);

FIG. 7 shows a front isometric view of the stand of the present invention in an open position, with the bottom panel coupled with the back panel;

FIG. 8 shows the stand of the present invention as shown in FIG. 6, with a large electronic device leaning on the upper edges of the side panels in a longitudinally oriented manner; and,

FIGS. 9a and 9b show the stand of the present invention in a partially collapsed position (FIG. 9a) and a fully collapsed (closed) position (FIG. 9b).

### DETAILED DESCRIPTION OF THE PREFERRED EMBODIMENTS

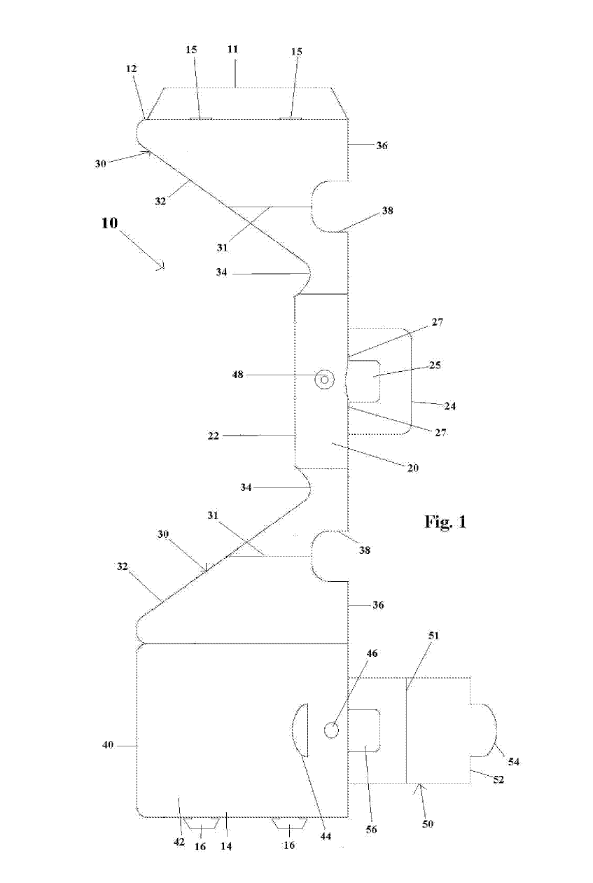

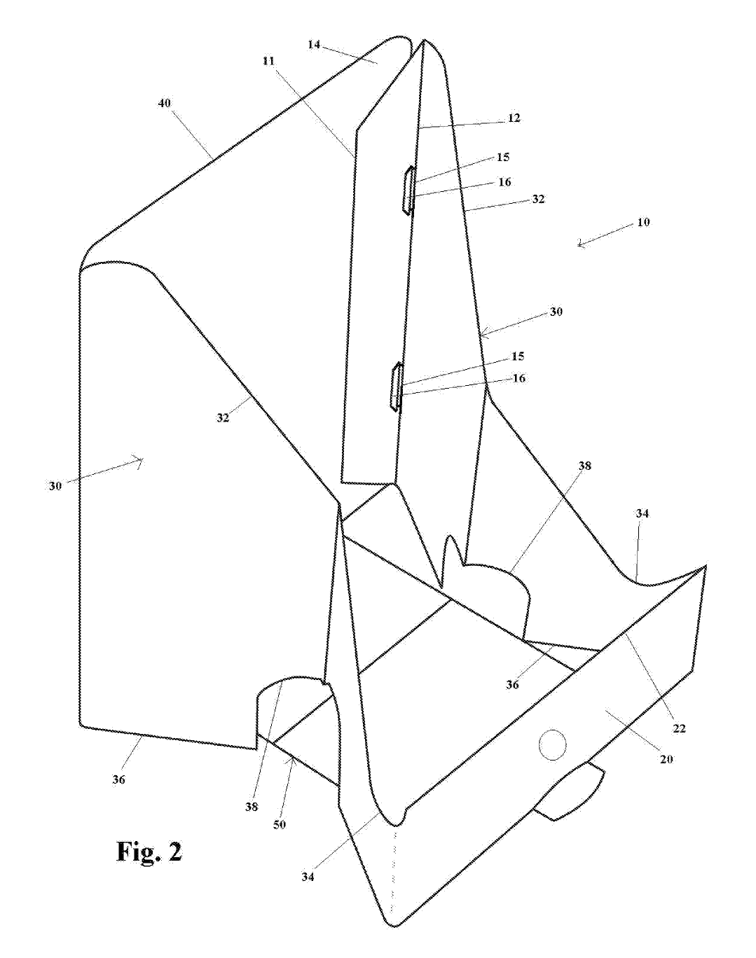

A preferred embodiment of the stand of the present invention is shown in FIG. 1 in an unassembled flat view, generally designated by the numeral (10), and in an assembled front isometric view in FIG. 2. Preferably, stand (10) is manufactured from a thin, semi-rigid material such as polypropylene. Stand (10) is preferably formed out of a single sheet and is assembled by joining the flap (11) extending from the first longitudinal end (12) with the second longitudinal end (14). This can be accomplished for example by inserting tabs 16 into slots 15, or by glue or other adhesive means.

Referring to the assembled view in FIG. 2, in which stand (10) is in the open position, stand (10) is shown comprising a front panel (20), two side panels (30), a back panel (40) and a bottom panel (50). Side panels (30) are foldable (collapsible) and unfoldable for selectively shifting stand (10) between the open position and the closed position, as described in greater detail herein below.

Each side panel (30) comprises an upper vertical edge (32) extending descendingly from the vertically higher back panel (40) to the vertically lower front panel (20). A portion (34) of each vertical edge (32) near front panel (20) extends vertically lower than the upper edge (22) (or, the height) of front panel (20), forming a seat for allowing an electronic device (not shown) to rest in vertically lower portion (34) when stand (10) is in the open position.

Lower vertical edge (36) of each side panel (30) extends from back panel (40) to front panel (20). A cutout portion (38) is cut into lower vertical edge (36) of each side panel (30), for exposing a portion of back panel (40) when stand (10) is in the closed position, as described in greater detail herein below.

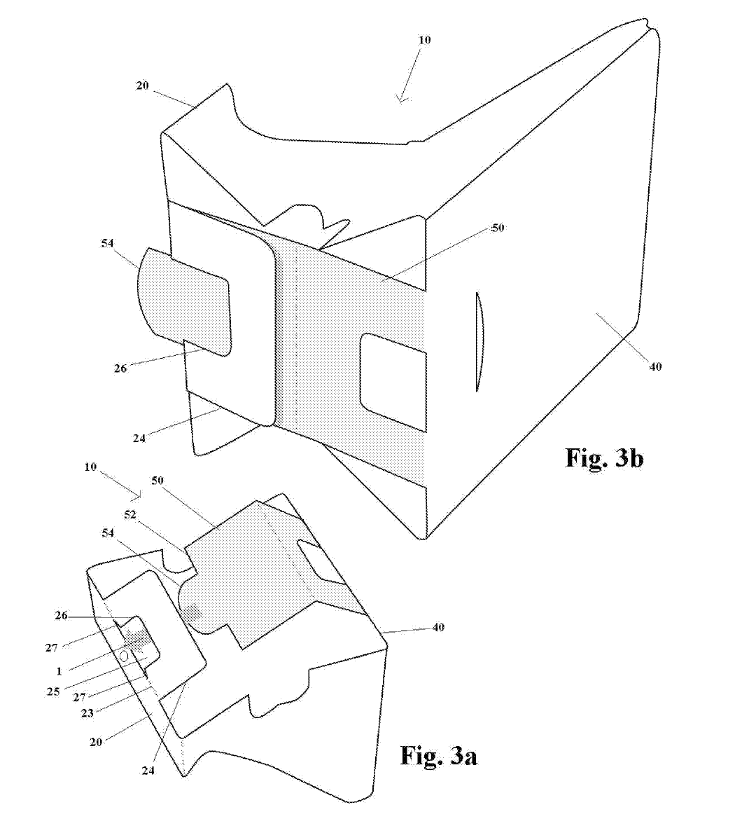

A bottom isometric view of stand (10) in the open position is shown in FIGS. 3a and 3b, with bottom panel (50) in a preparatory position for coupling with front panel (20) (FIG. 3a), and coupled with front panel (20) (FIG. 3b).

In a preferred aspect of the present invention, bottom panel (50) extends from back panel (40) and comprises a free end (52) having a coupling member (54) extending therefrom. Front panel (20) comprises an extension element (24) having a receiving portion (26) for joining coupling member (54) to front panel (20), as indicated by arrow (1) in FIG. 3a, and shown assembled in FIG. 3b. Receiving portion (26) is an opening in extension element (24) for inserting the coupling member therein. Receiving portion (26) is preferably an opening created at the juncture (23) between extension element (24) and the front panel (20). The opening preferably comprises slits (27) for allowing coupling member (54) to be inserted through the opening, while preventing coupling member (54) from being released unintentionally from the opening.

According to another aspect (not shown) receiving portion (26) is an opening in front panel (20) for inserting coupling member (54) therein (i.e. without the extension element). The opening preferably comprises slits (27) for allowing coupling member (54) to be inserted through the opening, while preventing coupling member (54) from being released unintentionally from the opening.

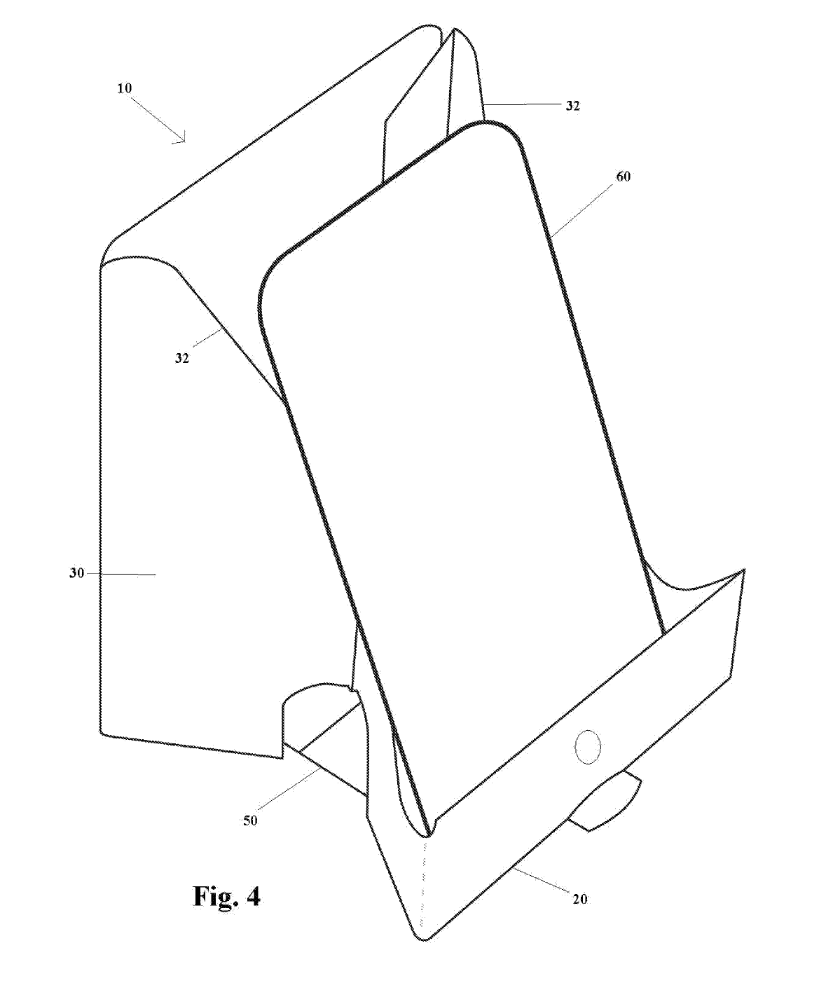

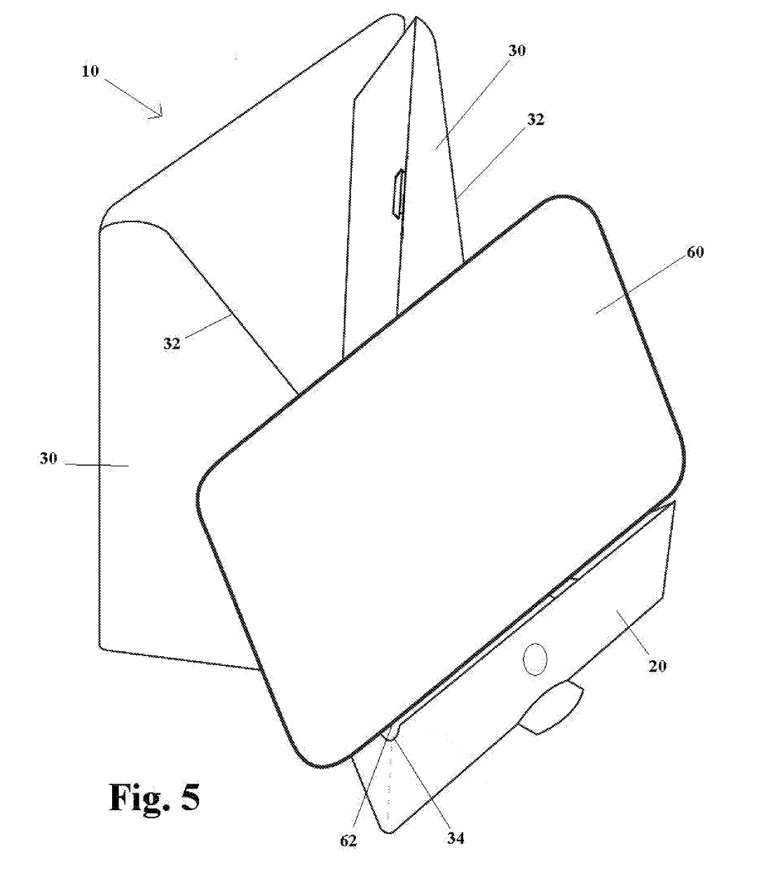

With reference to FIGS. 4 and 5, when stand (10) is in the open position and bottom panel (50) joined with front panel (20), a portable electronic device (60), is supported by stand (10). FIG. 4 shows an example of a small device (60), such as an iPhone, leaning on upper edges (32) of side panels (30) in a longitudinally oriented manner. The lower longitudinal edge of device (60) rests on lower panel (50) and is prevented from sliding forward by front panel (20). FIG. 5 shows an example of a small device (60), such as an iPhone, leaning on upper edges (32) of side panels (30) in a transversally oriented manner. Transverse edge (62) of device (60) rests in the seat formed in portion (34) near front panel (20), thereby preventing device (60) from sliding forward.

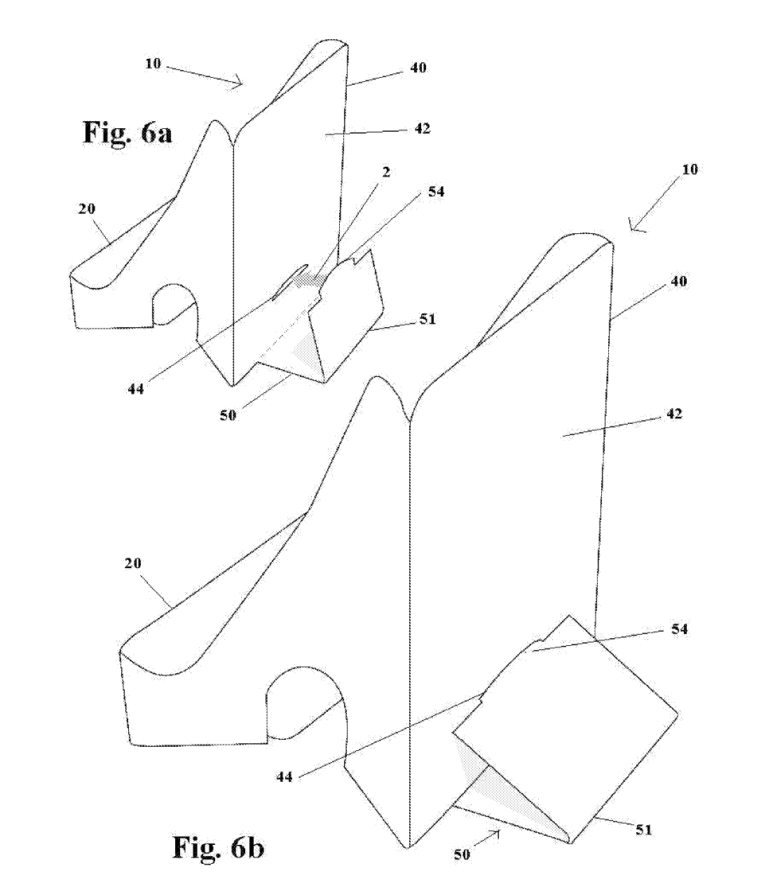

When it is desired for stand (10) to support a large portable electronic device, such as an iPad or e-book reader, stand (10) may require an additional “leg” to maintain stand (10) in a stable position and prevent toppling over backwards. Referring to FIGS. 6a and 6b, stand (10) is shown in a back isometric view, wherein bottom panel (50) is shown extending behind back panel (40) in a preparatory position (FIG. 6a), wherein back panel (40) comprises a first surface (not shown) facing front panel (20) and a second surface (42) facing away from front panel (20). Coupling member (54) of bottom panel (50) is folded (or, bent) upwards along an optional crease (51) (see also FIG. 1) and is inserted through the receiving portion (44), as indicated in FIG. 6a by arrow (2), and shown assembled in FIG. 6b. Receiving portion (44) comprises an opening at second surface (42) of back panel (40), optionally located approximately at the same height as the top edge of front panel (20). The opening preferably comprises at least one slit (not shown) for allowing coupling member (54) to be inserted through the opening, while preventing coupling member (54) from being released unintentionally from the opening.

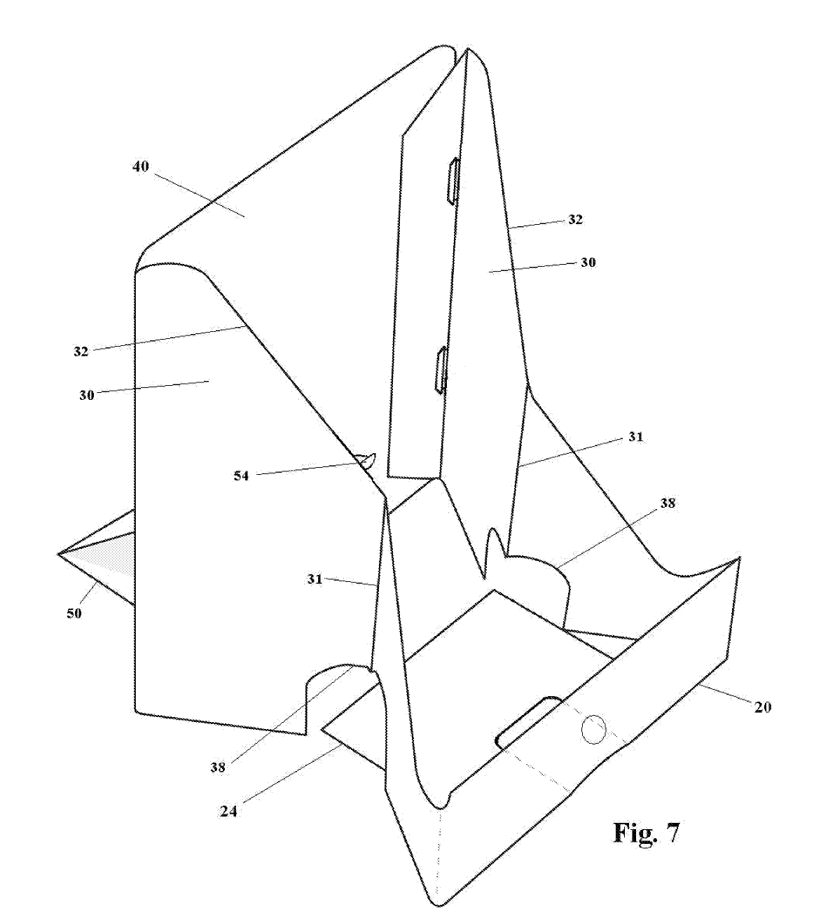

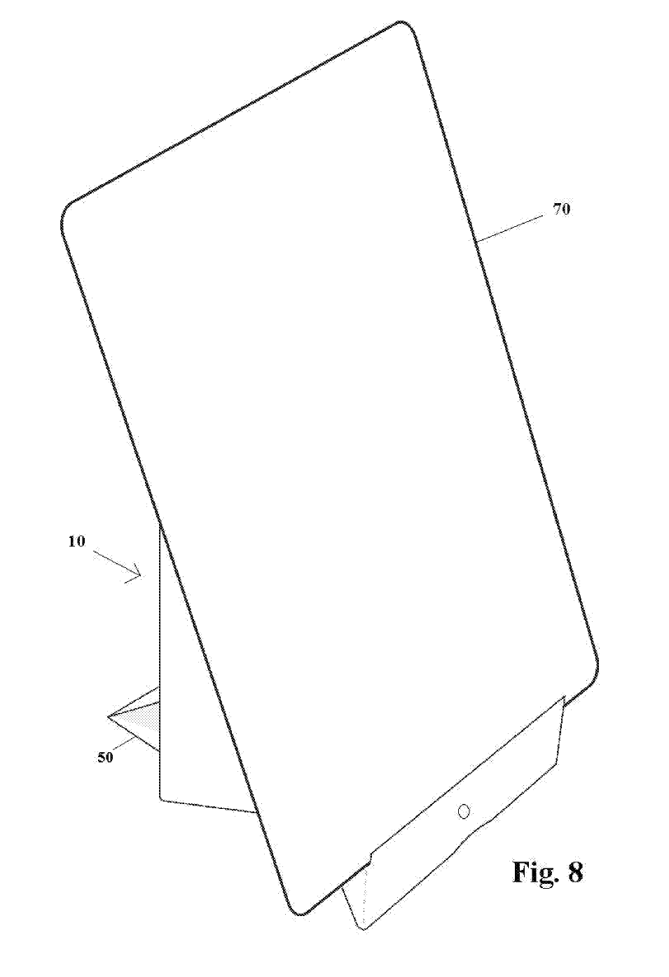

FIGS. 7 and 8 show stand (10) in the open position in a front isometric view, with coupling member (54) of bottom panel (50) inserted through the receiving portion of back panel (40) for supporting a large portable electronic device (70) (see FIG. 8). In FIG. 7, extension element (24) of front panel (20) is seen extending toward back panel (40). When stand (10) is arranged for supporting a large portable electronic device, extension element (24) is extraneous to stand (10).

In FIG. 7 each side panel (30) is foldable and unfoldable for selectively shifting the stand between the closed position and the open position. An optional folding line (31) extends from cutout portion (38) to upper edge (32) of side panels for indicating the preferred location of folding side panels (30).

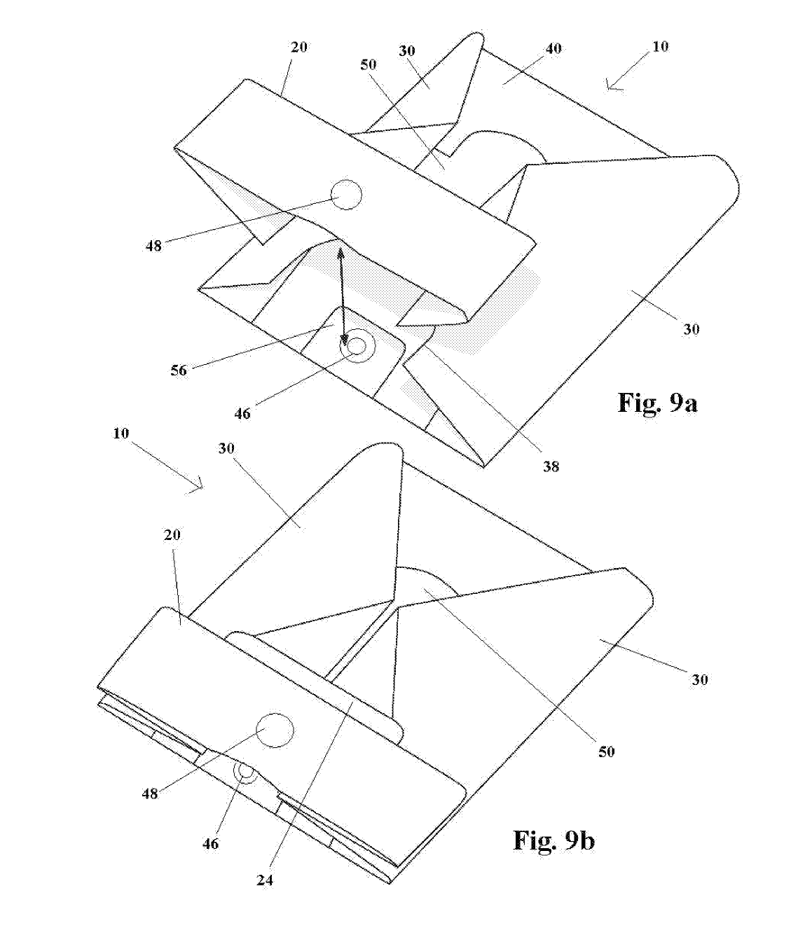

When stand (10) is in the closed position, the folded side panels (30) cover at least a portion of back panel (40). FIG. 9a shows side panels (30) partially collapsed by folding (bending) each side wall (30) inward, toward the central longitudinal axis of stand (10). Bottom panel (50) is shown folded (bent) upward such that the opening (56) in bottom panel (50) exposes a portion of back panel (40). Similarly, as best seen in FIG. 9b, extension element (24) is folded (bent) upward such that the opening (25) (see FIG. 1) exposes a portion of front panel (20).

A first component (46) of the coupling mechanism is located on the exposed portion of back panel (40) and a second component (48) of the coupling mechanism (illustratively indicated on the outer surface of front panel (20)) is located on the opposing face (not shown), on the exposed portion of front panel (20). Cutout portions (38) of side panels (30) are positioned around the portion of back panel (40) having a first component (46) of the coupling mechanism.

When stand (10) is in the closed position front panel (20) is releasably securable to back panel (40) by the coupling mechanism. In one aspect, the coupling mechanism comprises a snap mechanism, wherein front panel (20) comprises a snap stud and back panel (40) comprises a snap socket. Alternatively, back panel (40) comprises a snap stud and front panel (20) comprises a snap socket. In an alternative embodiment, the coupling mechanism comprises hook and loop fasteners. In yet an alternative aspect, the coupling mechanism comprises an adhesive material such as Velcro on at least one of the front panel and back panel for selectively securing and releasing either front panel (20) from back panel (40) or back panel (40) from front panel (20).

In an alternative embodiment of the present invention (not shown) a collapsible stand for supporting a portable electronic device is provided. The stand comprises a front panel, two side panels and a back panel, and an open position and a closed position. The stand is selectively shiftable between the open position and the closed position, and wherein when the stand is in the closed position the front panel is releasably securable to the back panel by a coupling mechanism.

It is understood that the above description of the embodiments of the present invention are for illustrative purposes only, and is not meant to be exhaustive or to limit the invention to the precise form or forms disclosed, as many modifications and variations are possible. Such modifications and variations are intended to be included within the scope of the present invention as defined by the accompanying claims.

1. A stand for supporting a portable electronic device, said stand comprising a front panel, two side panels, a back panel and a bottom panel, wherein said stand comprises an open position and a closed position, and wherein said stand is selectively shiftable between said open position and said closed position, and wherein when said stand is in said open position said bottom panel is selectively coupled with at least one of said front panel and said back panel.

2. The stand of claim 1, wherein each side panel is foldable and unfoldable for selectively shifting said stand between the closed position and the open position.

3. The stand of claim 1, wherein each side panel comprises an upper vertical edge, wherein said edge extends from the back panel to the front panel, and wherein said back panel is vertically higher than said front panel such that said edge extends descendingly from said back panel to said front panel.

4. The stand of claim 3, wherein a portion of each vertical edge near the front panel extends vertically lower than the height of the front panel for allowing an electronic device to rest in the vertically lower portion when said stand is in the open position.

5. The stand of claim 2, wherein when said stand is in the closed position, the folded side panels cover at least a portion of the back panel.

6. The stand of claim 5, wherein each side panel comprises a lower vertical edge, wherein said edge extends from the back panel to the front panel, and wherein said edge comprises a cutout portion cut into said side panel, wherein when said stand is in the closed position a portion of said back panel is exposed by said cutout portions of said side panels.

7. The stand of claim 6, wherein when said stand is in the closed position the front panel is releasably securable to the back panel by a coupling mechanism.

8. The stand of claim 7, wherein the coupling mechanism comprises a first component located on the exposed portion of the back panel and a second component located on the opposing face of the front panel.

9. The stand of claim 8, wherein the coupling mechanism comprises a snap mechanism, wherein one of the front panel and the back panel comprises a snap stud and the other of said front panel and said back panel comprises a snap socket.

10. The stand of claim 8, wherein the coupling mechanism comprises hook and loop fasteners, wherein one of the front panel and the back panel comprises hook fasteners and the other of said front panel and said back panel comprises loop fasteners such as exist in Velcro™

11. The stand of claim 8, wherein the coupling mechanism comprises an adhesive material on at least one of the front panel and back panel for selectively securing and releasing one of said front panel and back panel to the other of said front panel and back panel.

12. The stand of claim 1, wherein the bottom panel extends from the back panel and comprises a free end having a coupling member, and wherein said front panel comprises a receiving portion for joining said coupling member to said front panel.

13. The stand of claim 12, wherein the receiving portion is an opening in the front panel for inserting said coupling member therein.

14. The stand of claim 13, wherein the opening comprises a slit for allowing the coupling member to be inserted through said opening, while preventing said coupling member from being released unintentionally from said opening.

15. The stand of claim 1, wherein the bottom panel extends from the back panel and comprises a free end having a coupling member, and said front panel comprises an extension element having a receiving portion for joining said coupling member thereto.

16. The stand of claim 15, wherein the receiving portion is an opening in the extension element for inserting the coupling member therein.

17. The stand of claim 15, wherein the receiving portion is an opening created at the juncture between the extension element and the front panel.

18. The stand of any one of claims 16 and 17, wherein the opening comprises a slit for allowing the coupling member to be inserted through said opening, while preventing said coupling member from being released unintentionally from said opening.

19. The stand of claim 1, wherein the bottom panel extends from the back panel and comprises a free end having a coupling member, and wherein said back panel comprises a receiving portion for joining said coupling member to said back panel.

20. The stand of claim 19, wherein the receiving portion is an opening in the back panel for inserting said coupling member therein.

21. The stand of claim 20, wherein the opening comprises at least one slit for allowing the coupling member to be inserted through said opening, while preventing said coupling member from being released unintentionally from said opening.

22. The stand of claim 19, wherein the bottom panel extends behind the back panel, wherein back panel comprises a first surface facing the front panel and a second surface facing away from said front panel, wherein the coupling member is inserted through the opening at said second surface of said back panel.

23. The stand of claim 1, wherein the portable electronic device may be chosen from the list consisting of a cellular phone, iPhone, iPad, iTouch, ebook reader, Playstation, or other similar devices.

24. A stand for supporting a portable electronic device, said stand comprising a front panel, two side panels and a back panel, wherein said stand comprises an open position and a closed position, and wherein said stand is selectively shiftable between said open position and said closed position, and wherein when said stand is in said closed position said front panel is releasably securable to the back panel by a coupling mechanism.
